(19) United States
(12) Patent Application Publication
(10) Pub. No.: US 2012/0114961 A1
(43) Pub. Date: May 10, 2012

(54) BULK NANOCOMPOSITE THERMOELECTRIC MATERIAL, NANOCOMPOSITE THERMOELECTRIC MATERIAL, AND METHOD OF PREPARING THE BULK NANOCOMPOSITE THERMOELECTRIC MATERIAL

(75) Inventors: Kyu-hyoung LEE, Yongin-si (KR); Hyun-sik KIM, Seoul (KR); Sang-mock LEE, Yongin-si (KR); Eun-sung LEE, Hwaseong-si (KR); Sang-soo JEE, Hwaseong-si (KR); Il-ho KIM, Chungju-si (KR)

(73) Assignees: Chungju National University Industry-Academic Cooperation Foundation, Chungju-si (KR); SAMSUNG ELECTRONICS CO., LTD.,, Suwon-si (KR)

(21) Appl. No.: 13/243,309

(22) Filed: Sep. 23, 2011

(30) Foreign Application Priority Data
Oct. 8, 2010 (KR) 10-2010-0098341

(51) Int. Cl. B22F 1/02; B22F 1/00; B22F 3/10; H01L 35/14

(52) U.S. Cl. 428/570; 75/228; 419/31; 419/23

(57) ABSTRACT

A bulk nanocomposite thermoelectric material including: a plurality of grains of a thermoelectric material; and a metal nanolayer on a boundary of the plurality of grains, wherein the metal nanolayer is crystalline, and a glass transition temperature and a crystallization temperature of the nanometal are lower than a melting point of the thermoelectric material.

### CROSS-REFERENCE TO RELATED APPLICATIONS

This application claims priority to Korean Patent Application No. 10-2010-0098341, filed on Oct. 8, 2010, and all the benefits accruing therefrom under 35 U.S.C. §119, the content of which in its entirety is herein incorporated by reference.

### BACKGROUND

1. Field

The present disclosure relates to thermoelectric materials and methods of preparing the same, and more particularly, to a nanocomposite thermoelectric material and a method of preparing the same.

2. Description of the Related Art

The thermoelectric effect provides reversible and direct conversion of energy between heat and electricity. The thermoelectric effect is governed by the movement of charge carriers, i.e., electrons and holes, inside a material.

In the Seebeck effect, a temperature difference is directly converted into electricity. The Seebeck effect is useful for power generation and uses an electromotive force generated from a temperature difference between two ends of a thermoelectric material. In the Peltier effect, heat is generated at an upper junction of two different materials and is absorbed at a lower junction of the two different materials when electrical current is passed. The Peltier effect is useful for cooling applications and uses a temperature difference generated when an electrical current applied between two ends of the thermoelectric material. The Seebeck effect and the Peltier effect are different from Joule heating because they are thermodynamically reversible.

Currently, thermoelectric materials are used in active cooling systems of semiconductor equipment and other electronic devices in which it is difficult to sufficiently reduce heat generation using a passive cooling system. Demand for thermoelectric materials has increased for applications where reduction of heat generation is difficult using a refrigerant gas compression method. Also, precise temperature control systems using thermoelectric materials have been applied to deoxyribonucleic acid (“DNA”) research. Further, thermoelectric cooling is a vibration-free, low noise, and environmental-friendly cooling technology that does not use a refrigerant gas that can be an environmental hazard. Also, if the cooling efficiency of thermoelectric cooling materials can be improved, the number of applications of thermoelectric cooling materials may be increased to include general-purpose cooling, such as commercial or residential refrigerators or air conditioners. Also, when thermoelectric materials are used in heat emitting car engine components, or an industrial factory, or the like, electrical power may be generated using a temperature difference generated at two ends of the thermoelectric material. Thus, thermoelectric materials have received attention as a renewable energy source. Such a thermoelectric power generation system has been already used in space exploration satellites to Mars or Saturn where solar energy cannot be used.

The performance of the thermoelectric material may be assessed using a dimensionless figure of merit ZT, defined by Equation 1 below.

### Equation 1

$$ZT = \frac{{S}^{2} σ T}{κ}$$

In Equation 1. S denotes a Seebeck coefficient (i.e., the thermoelectric power generated from a temperature difference of 1° C.), a denotes the electrical conductivity, T denotes an absolute temperature, and K denotes the thermal conductivity. As is apparent from Equation 1, in order to increase the ZT value of the thermoelectric material, the Seebeck coefficient and the electrical conductivity, i.e., a power factor (S²σ), must be increased or the thermal conductivity must be decreased, or both.

However, the Seebeck coefficient has an inversely proportional (i.e., a trade-off) relationship with the electrical conductivity, and thus, when the Seebeck coefficient increases, the electrical conductivity decreases, or vice versa, according to a change of concentration of electrons or holes, i.e., carriers. For example, a metal having high electrical conductivity can have a low Seebeck coefficient, and an insulating material having low electrical conductivity can have a high Seebeck coefficient. Accordingly, the inversely proportional relationship between the Seebeck coefficient the electrical conductivity is a significant restriction on increasing the power factor.

Using nanostructuring technology that has been developed since the late 1990s, it is possible to prepare a superlattice thin film, a nanowire, or a quantum dot. Thus, while not wanting to be bound by theory, it is understood that the Seebeck coefficient can be increased using a quantum confinement effect or the thermal conductivity can be decreased using a phonon glass electron crystal (“PGEC”) concept, thus it is at least theoretically possible to provide improved thermoelectric performance using the quantum confinement effect and/or the phonon glass electron crystal concept.

In the quantum confinement effect, an effective mass of a carrier is increased by increasing a density of states (“DOS”) of the carrier in a material to increase the Seebeck coefficient, and in this case, the electrical conductivity of the material does not significantly change.

FIGS. 1A to 1C show graphs of schematic shapes of a DOS function of an electron in a low-dimensional structure. Referring to FIGS. 1A to 1C, respectively, the DOS function increases in a stepwise manner in a 2-dimensional (“2D”) quantum well, and the DOS function increases infinitely in a one dimensional (“1D”) quantum wire and in a dimensionless quantum dot. As is also shown in FIGS. 1A to 1C, and while not wanting to be bound by theory, it is understood that the DOS increases more rapidly in a lower dimensional nanostructure. Also, when the DOS increases, an effective mass increases, and when the effective mass increases, the Seebeck coefficient increases.

While not wanting to be bound by theory, in the PGEC concept, thermal conductivity is reduced without deteriorating the electrical conductivity by blocking a movement of a phonon, which provides heat transfer, while not interfering with movement of a charge carrier.

FIG. 2 is a diagram describing the PGEC concept. Referring to FIG. 2, from among the phonons 1 and the charge carrier electrons 2, which transfer heat from a high temperature surface 3 to a low temperature surface 4 of a material, only the phonons hit barriers and are stopped, whereas the charge carrier electrons move without being stopped. Accordingly, a portion of the thermal conductivity attributable to the phonons is reduced but the electrical conductivity attributable to the charge carrier electrons is not reduced.

However, high efficiency nanostructured thermoelectric materials using the quantum confinement effect and the PGEC method which have been developed until now have been in the form of a thin film, and thus, commercialization thereof is difficult due to the limitations of thin films. Thus there remains a need for nanostructured thermoelectric materials in bulk form.

### SUMMARY

Provided is a powder of a thermoelectric material, which has high thermoelectric performance by providing a bulk material having both a quantum confinement effect and a phonon glass electron crystal (“PGEC”) concept in the bulk material. Also disclosed is a method of preparing the thermoelectric material.

Additional aspects will be set forth in part in the description which follows and, in part, will be apparent from the description.

According to an aspect, a bulk nanocomposite thermoelectric material includes: a plurality of grains of a thermoelectric material; and a metal nanolayer on a boundary of the plurality of grains, wherein the nano metal is crystalline, and a glass transition temperature and a crystallization temperature of the nano metal are lower than a melting point of the thermoelectric material.

Each grain of the plurality of grains may have a diameter of about 1 nanometer to about 100 micrometers.

The metal nanolayer may have a thickness of about 1 nanometer to about 50 nanometers.

The thermoelectric material may include a bismuth-tellurium (Bi—Te) material including at least two elements of Bi, antimony (Sb), Te, and selenium (Se); a lead-Te (Pb—Te) material including Pb and Te; a cobalt-Sb (Co—Sb) material including Sb and at least one of Co and iron (Fe); a silicon-germanium (Si—Ge) material including Si and Ge; or a Fe—Si material including Fe and Si.

The metal nanolayer may include an alloy of Formula 1:

AaBbCcDdEeFf, Formula 6

wherein in Formula 1, A, B, C, D, E, and F are each a different element; A is Al, Cu, Fe, Ni, Mg, Mn, Ca, Ti, or Zr; B is Y, Ni, Zr, Ti, Gd, Hf, B, Nb, Cu, Al, Ag, Zn, Mg, or Be; C is Fe, Ce, Sm, Y, Gd, Dy, Er, La, Al, Zr, Ti, Ag, Be, Nb, Ni, Mo, Mn, Ta, P, Y, Cu, or Mg; D is V, Ti, Co, Ni, Ag, Al, In, Nb, Ta, Y, Nb, Si, Sn, Cu, Gd, Y, Pd, Zn, or C; E is O, Si, Ni, Sn, Ag, Co, Al, Y, Pd, or Be; F is Si, Zn, C, Y, Nb, or Zr; and 20≦a≦90, 2≦b≦50, 0≦c≦30, 0≦d≦12, 0≦e≦10, 0≦e≦10, 0≦f≦7, and a+b+c+d+e+f=100.

The metal nanolayer may include at least a first layer and a second layer, each of the at least a first layer and a second layer may include a crystalline alloy, and at least one of a glass transition temperature or a crystallization temperature of the first layer may be different than a glass transition temperature or a crystallization temperature of the second layer, respectively.

According to another aspect, disclosed is a nanocomposite thermoelectric material including: a bulk thermoelectric material; and a metal nanolayer on a surface of the thermoelectric material, wherein the metal nanolayer includes an amorphous metal.

According to another aspect, disclosed is a method of preparing a bulk nanocomposite thermoelectric material, the method including: forming a powder of a thermoelectric material; forming a powder of an amorphous metal having a glass transition temperature and a crystallization temperature that are lower than a melting point of the thermoelectric material; combining the powder of the thermoelectric material and the powder of the amorphous metal to form a combination; firstly heat treating the combination at about the glass transition temperature of the amorphous metal to wet a surface of the powder of the thermoelectric material with the amorphous metal; secondly heat treating the firstly heat treated combination at or above the crystallization temperature of the amorphous metal to crystallize the amorphous metal; and sintering the secondly heat treated combination at or above a melting point of the thermoelectric material to prepare the bulk nanocomposite thermoelectric material.

### BRIEF DESCRIPTION OF THE DRAWINGS

These and/or other aspects will become apparent and more readily appreciated from the following description of the embodiments, taken in conjunction with the accompanying drawings in which:

FIGS. 1A to 10 are each a graph of the density state of electrons (N(E)) versus energy (electron volts, eV) and a corresponding schematic shape showing a density of states function of an electron in a low-dimensional structure;

FIG. 2 is a diagram describing an embodiment of a phonon glass electron crystal (“PGEC”) concept;

FIG. 3 is a diagram schematically illustrating an embodiment of a bulk nanocomposite thermoelectric material;

FIG. 4 is a graph of energy (arbitrary units) versus density of states (arbitrary units) and is an energy band diagram describing a carrier filtering effect;

FIG. 5 is a flowchart illustrating an embodiment of a method of preparing a nanocomposite thermoelectric material;

FIG. 6 is a diagram schematically illustrating an embodiment of a process of forming a combination of a powder of the thermoelectric material and a powder of an amorphous metal;

FIG. 7 is a diagram schematically illustrating an embodiment of a process of wetting a surface of the powder of the thermoelectric material with the amorphous metal by heat treating the combination;

FIG. 8 is diagram schematically illustrating an embodiment of a process of changing a nanolayer of an amorphous metal on a surface of the powder of the thermoelectric material to a nanolayer of a crystalline metal;

FIG. 9 is a scanning electron micrograph (“SEM”) of the powder of an amorphous metal synthesized via gas atomization;

FIG. 10 is a cross-sectional SEM of a bulk nanocomposite thermoelectric material according to Example 1, wherein a crystallized Cu₄₃Zr₄₃Al₇Ag₇ nanolayer is coated on a surface of Bi_{0.5}Sb_{1.5}Te₃;

FIG. 11A is a graph of electrical conductivity (Siemens per centimeter, S/cm) versus temperature (Kelvin, K) showing thermoelectric characteristics of the thermoelectric materials of Examples 1 and 2 and the Comparative Example;

FIG. 11B is a graph of Seebeck coefficient (microvolts per Kelvin, μV/K) versus temperature (Kelvin. K) showing thermoelectric characteristics of the thermoelectric materials of Examples 1 and 2 and the Comparative Example;

FIG. 11C is a graph of power factor (watts per square milliKelvin, W/mK²) versus temperature (Kelvin, K) showing thermoelectric characteristics of the thermoelectric materials of Examples 1 and 2 and the Comparative Example;

FIG. 11D is a graph of thermal conductivity (watts per milliKelvin, W/mK) versus temperature (Kelvin, K) showing thermoelectric characteristics of the thermoelectric materials of Examples 1 and 2 and the Comparative Example;

FIG. 11E is a graph of the lattice contribution to thermal conductivity (watts per milliKelvin, W/mK) versus temperature (Kelvin, K) showing thermoelectric characteristics of the thermoelectric materials of Examples 1 and 2 and the Comparative Example;

FIG. 11F is a graph of dimensionless figure of merit (ZT) versus temperature (Kelvin, K) showing thermoelectric characteristics of the thermoelectric materials of Examples 1 and 2 and the Comparative Example; and

FIG. 12 is a graph of electrical conductivity (Siemens per centimeter, S/cm) versus temperature (Kelvin, K) showing thermoelectric characteristics of the thermoelectric materials of Examples 3 and 4 and the Comparative Example;

FIG. 12B is a graph of Seebeck coefficient (microvolts per Kelvin, μV/K) versus temperature (Kelvin, K) showing thermoelectric characteristics of the thermoelectric materials of Examples 3 and 4 and the Comparative Example;

FIG. 12C is a graph of power factor (watts per square milliKelvin, W/mK²) versus temperature (Kelvin. K) showing thermoelectric characteristics of the thermoelectric materials of Examples 3 and 4 and the Comparative Example;

FIG. 12D is a graph of thermal conductivity (watts per milliKelvin, W/mK) versus temperature (Kelvin, K) showing thermoelectric characteristics of the thermoelectric materials of Examples 3 and 4 and the Comparative Example;

FIG. 12E is a graph of the lattice contribution to thermal conductivity (watts per milliKelvin, W/mK) versus temperature (Kelvin, K) showing thermoelectric characteristics of the thermoelectric materials of Examples 3 and 4 and the Comparative Example; and

FIG. 12F is a graph of dimensionless figure of merit (ZT) versus temperature (Kelvin, K) showing thermoelectric characteristics of the thermoelectric materials of Examples 3 and 4 and the Comparative Example.

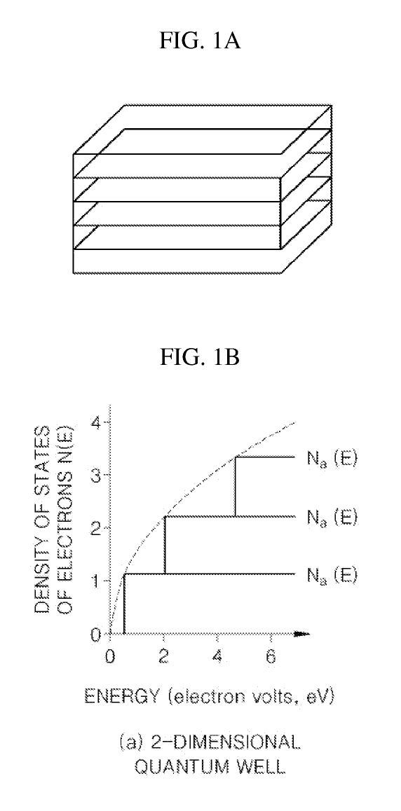

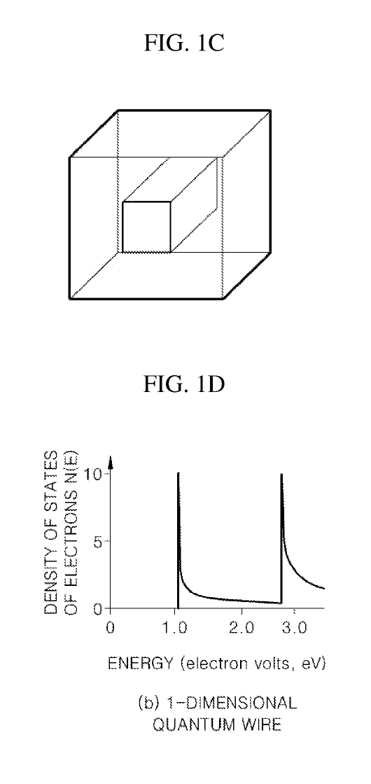

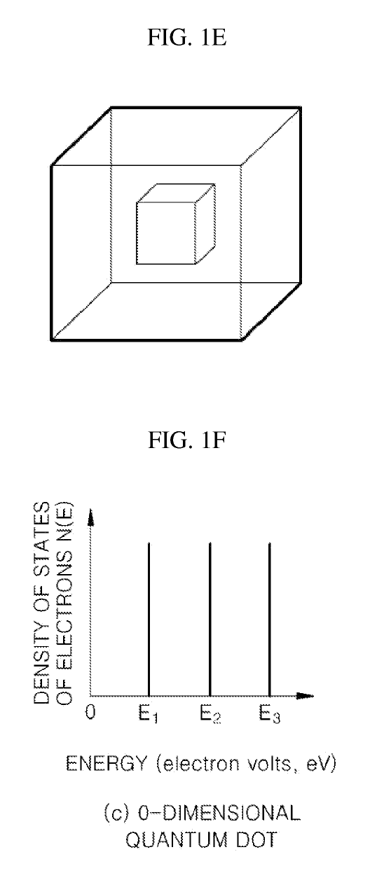

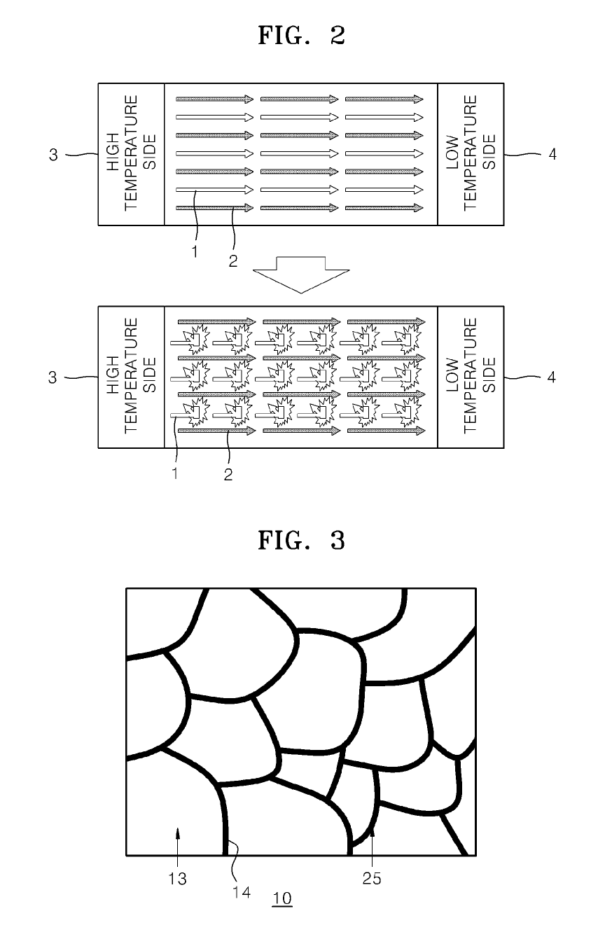

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms “first,” “second,” “third” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stared features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The term “nanocomposite” denotes a structure having a portion having a size larger than a nanometer scale and having a portion having a size of a nanometer scale.

Also, the term “bulk” (e.g., “bulk” material) refers to a structure having a volume that is larger than individual grains of a powder. A bulk material can be a plurality of grains of a powder, wherein the powder comprises grains having a size on a nanometer or a micrometer scale.

An embodiment of the thermoelectric material will now be disclosed in further detail.

FIG. 3 is a diagram schematically illustrating an embodiment of a bulk nanocomposite thermoelectric material 10.

The bulk nanocomposite thermoelectric material 10 includes a plurality of grains 13 of a thermoelectric material and a metal nanolayer 25, i.e. a metal layer of nanometer scale thickness, on a boundary 14 of the plurality of grains 13. Each grain may have a diameter of about 1 nanometer (nm) to about 100 micrometers (μm), specifically about 10 nm to about 10 μm, more specifically about 100 nm to about 1 μm. The plurality of grains may have an average diameter (e.g., an average largest particle diameter) of about 1 nanometer (nm) to about 100 micrometers (μm), specifically about 10 nm to about 10 μm, more specifically about 100 nm to about 1 μm. The metal nanolayer 25 may have a thickness of about 1 nm to about 50 nm, specifically about 2 nm to about 40 nm, more specifically about 4 nm to about 30 nm.

The thermoelectric material of the plurality of grains 13 may comprise, consist essentially of, or consist of, for example, a bismuth-tellurium (Bi—Te), lead-Te (Pb—Te), cobalt-antimony (Co—Sb), silicon-germanium (Si—Ge), or iron-silicon (Fe—Si) material. The Bi—Te material may include at least two of Bi, Sb, Te, and selenium (Se). The Pb—Te material includes both Pb and Te, and may optionally include another element. The Co—Sb material may include Sb and at least one of Co and Fe. The Si—Ge material may include both Si and Ge. The Fe—Si material may include both of Fe and Si. In an embodiment, the thermoelectric material may comprise a Bi₂Te₃ alloy, CsBi₄Te₆, CoSb₃, a PbTe alloy, Zn₄Sb₃, a Zn₄Sb₃ alloy, NaₓCoO₂, CeFe_{3.5}Co_{0.5}Sb₁₂, Bi₂Sr₂CO₂O_{y}, Ca₃CO₄O₉, or a Si_{0.8}Ge_{0.2} alloy. A combination comprising at least one of the foregoing can be used. Also, examples of the thermoelectric material are not limited thereto.

The metal nanolayer 25 comprises an amorphous metal having a glass transition temperature and a crystallization temperature that are lower than a melting point of the thermoelectric material. Because the metal nanolayer 25 has a thickness of about 1 nm to about 50 nm, specifically about 2 nm to about 40 nm, more specifically about 4 nm to about 30 nm, and has metal-like electrical conductivity, so as to provide a quantum confinement effect and a phonon glass electron crystal (“PGEC”) concept at the same time, the metal nanolayer 25 may comprise an amorphous metal that has excellent wettability with respect to a surface of the thermoelectric material, and high electrical conductivity. Such a metal nanolayer 25 may comprise an alloy having a low glass transition temperature in an amorphous state and good wettability. The metal nanolayer 25 may comprise an alloy comprising aluminum (Al), copper (Cu), nickel (Ni), or titanium (Ti) as a main component, but the main component of the alloy is not limited thereto. Alternatively, the metal nanolayer 25 may comprise a multilayer crystallized from a plurality of amorphous metals, wherein a first amorphous metal of the plurality of amorphous metals has a glass transition temperature or crystallization temperature that is different than a glass transition temperature or crystallization temperature, respectively, of a second amorphous metal of the plurality of amorphous metals. When the metal nanolayer 25 comprises a multilayer, a number of interfaces of a nanosized grain which scatters phonons increases, and thus the thermal conductivity of the nanocomposite thermoelectric material may be reduced. Alternatively, the metal nanolayer 25 may comprise an alloy crystallized from at least two types of amorphous metals having different glass transition temperatures or crystallization temperatures.

In a Bi₂Te₃-containing thermoelectric material, phonons have a mean free path of several nm, and electrons have mean free path of hundreds of nm, and thus have a mean free path that is much longer than that of the phonons. The phonons moving from a high temperature surface to a low temperature surface of the bulk nanocomposite thermoelectric material 10 are blocked by the metal nanolayer 25 on the boundary of the plurality of grains 13, and thus heat conduction is reduced. In other words, thermal conductivity is reduced as the phonons are scattered on the boundary of the plurality of grains 13. However, the electrons, having the longer mean free path, are able to pass through the plurality of grains 13 without being significantly or effectively stopped by the metal nanolayer 25 on the boundary of the plurality of grains 13, and thus the electrical conductivity of the thermoelectric material is not reduced or is insignificantly reduced.

In addition, and while not wanting to be bound by theory, it is believed that the metal nanolayer 25 may operate as an energy barrier so as to block electrons having an energy below a conduction band of the thermoelectric material and to allow to pass through only electrons having an energy above the conduction band, thereby producing a carrier filtering effect that filters out electrons having an energy equal to or less than that of an energy of the conduction band.

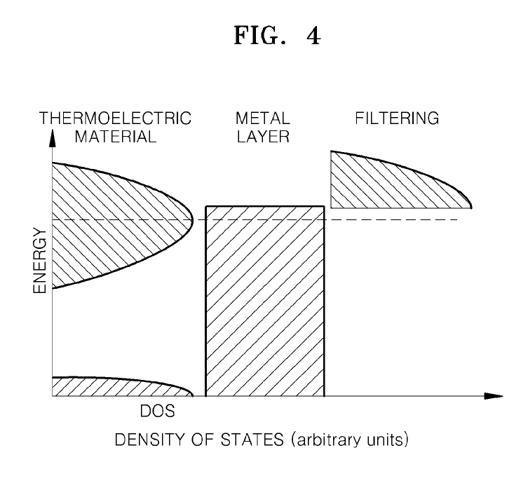

FIG. 4 is an energy band diagram describing the carrier filtering effect. Referring to FIG. 4, the electrons below the conduction band of the plurality of grains 13 are blocked from moving to another grain of the plurality of grains 13 because the energy band of the metal nanolayer 25 operates as a barrier. Only the electrons above the conduction band, which are not blocked by the energy band of the metal nanolayer 25, move to another grain of the plurality of grains 13. As a result, an energy width of the conduction band of the plurality of grains 13 is narrowed as the conduction band is filtered by the energy band of the metal nanolayer 25. Such a filtering effect is a quantum confinement effect in a broad sense. In other words, when a width of the energy band of the plurality of grains 13 increases, an effective mass of the electrons is increased, and thus the Seebeck coefficient may be increased, thereby increasing a power factor.

As such, the metal nanolayer 25 on the boundary of the plurality of grains 13 reduces the thermal conductivity attributable to phonon scattering, and increases the power factor according to the carrier filtering effect, i.e., the quantum confinement effect, thereby providing a bulk thermoelectric material having highly efficient thermoelectric performance.

An embodiment of a method of preparing a thermoelectric material will now be disclosed in further detail.

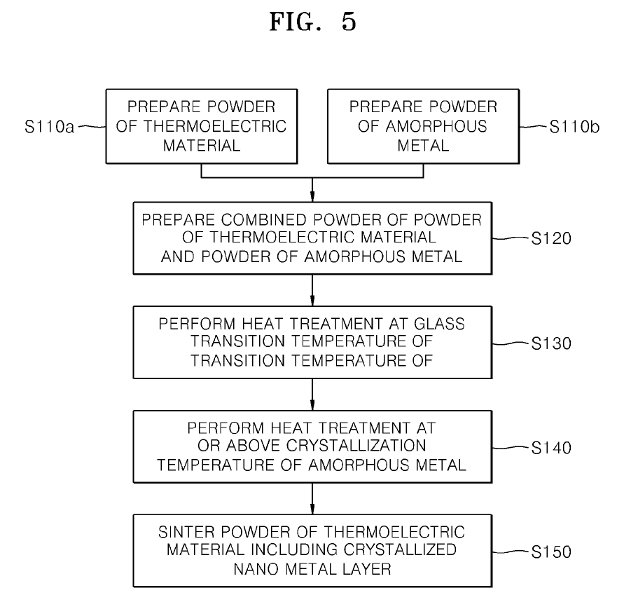

FIG. 5 is a flowchart illustrating an embodiment of a method of preparing a nanocomposite thermoelectric material.

Referring to FIG. 5, a powder of a thermoelectric material is prepared in operation S110a. For example, the powder of the thermoelectric material comprising the Bi—Te, Pb—Te, Co—Sb, Si—Ge, or Fe—Si material may be prepared as disclosed above, but a material of the thermoelectric material is not limited thereto. The powder of the thermoelectric material may be prepared via mechanically alloying by mixing a raw material powder, for example. The mechanical alloying is a method of alloying the raw material powder with a steel ball that mechanically impacts the raw material powder by disposing the raw material powder and the steel ball in ball mill, e.g., a jar of a hard metal, and rotating the jar. However, the method is not limited to the mechanical alloying. The powder of the thermoelectric material may have a size (e.g., average largest particle size) of about 1 nanometer (nm) to about 100 micrometers, (μm), specifically about 10 nm to about 10 μm, more specifically about 100 nm to about 1 μm.

Separately from operation S110a, a powder of an amorphous metal is prepared in operation S110b. The powder of the amorphous metal may be prepared by gas atomization or melt spinning, for example. Grains of the powder of the amorphous metal may have a size (e.g., average largest particle size) of about 1 nm to about 10 μm, specifically about 5 nm to about 5 μm, more specifically about 10 nm to about 1 μm.

Gas atomization is a method of dispersing a liquid metal into droplets by transferring kinetic energy from a supersonic jet of a gas to a liquid metal stream. In further detail, a combination of a raw material of the amorphous metal in a selected composition ratio is prepared to provide a combined raw material having a lump shape by melting and cooling the combination via arc melting under a vacuum or argon gas atmosphere. When the combined raw material turns into a liquid state upon heating the combined raw material at or above a melting point of the raw material, and an inert gas, such as an argon or nitrogen gas, is used to eject the melted combined raw material at a lower temperature (e.g., room temperature) while flowing the melted combined raw material through an injection nozzle, the melted combined raw material is quickly cooled down, and the powder of amorphous metal comprising spherical particles may be obtained.

Melt spinning is a method used to obtain the amorphous metal and includes rapid cooling by dropping a thin stream of liquid above a wheel that rotates and is internally cooled down by water or liquid nitrogen. In further detail, a combination including a raw material of the amorphous metal in a selected composition ratio is prepared to provide a combined raw material having a lump shape by melting and cooling the combination by using arc melting under a vacuum or argon gas atmosphere. When the combined raw material turns into a liquid state upon heating the combined raw material at or above a melting point of the raw material, and the melted combined raw material is ejected through a nozzle to a wheel that quickly rotates under a vacuum or argon gas atmosphere at room temperature, for example, and the amorphous metal having a ribbon shape may be obtained. Particles of the amorphous metal may be obtained by grinding the amorphous metal having the ribbon shape using a ball mill, or the like.

The amorphous metal may comprise a metal alloy. Any metal may be used as the amorphous metal as long as the metal has a glass transition temperature and a crystallization temperature that are lower than the melting point of the thermoelectric material. Here, the amorphous metal may have excellent wettability with respect to a surface of the powder of the thermoelectric material, and high electrical conductivity so as to simultaneously provide the quantum confinement effect and the PGEC concept. The amorphous metal may comprise an alloy comprising Al, Cu, Ni, or Ti as a main component.

Tables 1 through 5 below list representative alloys of the amorphous metal which may be used in an embodiment. Table 1 lists an alloy rich in Al, Table 2 lists an alloy rich in Cu, Table 3 lists an alloy rich in Fe or Ni, Table 4 lists an alloy rich in magnesium (Mg), manganese (Mn), or calcium (Ca), and Table 5 lists an alloy rich in Ti or zirconium (Zr). However, examples of the amorphous metal are not limited to the alloys listed in Tables 1 through 5.

In Tables 1 to 5, T_{g} refers to the glass transition temperature, Tₓ refers to the crystallization temperature, and T_{L} refers to the liquidus temperature.

TABLE 1
(Rich in Al)

| Alloy | T_{g} | Tₓ | T_{L} |
|---|---|---|---|
| Al88Y7Fe5 | 258 | 280 | 1000 |
| Al88Sm8Ni4 | 220 | 241 | 1000 |
| Al87.5Y7Fe5V0.5 | 280 | 340 | 960 |
| Al87.5Y7Fe5Ti0.5 | 275 | 310 | 950 |
| Al87Y7Fe5Ti1 | 270 | 340 | 960 |
| Al86Y7Fe5Ti2 | 280 | 350 | 995 |
| Al85Ni10Ce5 | 246 | 264 | 1000 |
| Al85.35Y8Fe6V0.65 | 285 | 365 | 1010 |
| Al85Y8Fe6V0.65O0.35 | 285 | 355 | 1012 |
| Al85Y8Ni5Co2 | 267 | 297 | 1000 |
| Al85Gd8Ni5Co2 | 281 | 302 | 1000 |
| Al85Dy8Ni5Co2 | 277 | 303 | 1000 |
| Al85Er8Ni5Co2 | 274 | 305 | 1000 |
| Al84Ni10Ce6 | 273 | 286 | 1000 |
| Al84Ni10La6 | 273 | 289 | 845 |
| Al84.35Y8Fe6V0.65O1 | 285 | 355 | 1000 |

TABLE 2
(Rich in Cu)

| Alloy | T_{g} | Tₓ | T_{L} |
|---|---|---|---|
| Cu30Ag30Zr30Ti10 | 393 | 427 | 794 |
| Cu40Ni20Zr30Ti10 | 454 | 476 | 944 |
| Cu40Ni5Ag15Zr30Ti10 | 424 | 454 | 797 |
| Cu43Zr43Al7Ag7 | 449 | 521 | 852 |
| Cu46Gd47Al7 | 245 | 266 | |
| Cu46Hf42.5Al7 | 519 | 551 | |
| Cu46Y42.5Al7 | 290 | 319 | |
| Cu46Zr46Al8 | 430 | 513 | 886 |
| Cu46Zr47Al7 | 445 | 504 | |
| Cu47.5Zr40Be12.5 | 425 | 483 | 825 |
| Cu47Ti33Nb11Ni8Si1 | 437 | 459 | 992 |
| Cu47Ti33Zr11In8Si1 | 430 | 460 | 816 |
| Cu47Ti33Zr11Ni6Ag2Si1 | 441 | 465 | |
| Cu47Ti33Zr11Ni6Co2Si1 | 447 | 491 | |
| Cu47Ti33Zr11Ni6Sn2Si1 | 436 | 489 | |
| Cu47Ti33Zr11Ni8Si1 | 447 | 484 | 884 |
| Cu47Ti33Zr9Nb2Ni8Si1 | 455 | 489 | |
| Cu47Ti33Zr9Y2Ni8Si1 | 429 | 456 | |
| Cu50Zr35Ti10Al5 | 427 | 468 | 848 |
| Cu50Zr40Ti10 | 387 | 435 | 880 |
| Cu50Zr43Al7 | 458 | 519 | 903 |
| Cu50Zr45Al5 | 434 | 494 | 862 |
| Cu50Zr50 | 402 | 451 | 957 |
| Cu57Zr28.5Ti9.5Ta5 | 456 | 478 | |
| Cu60Zr30Ti10 | 451 | 473 | 833 |
| Cu60Zr40 | 453 | 503 | 894 |

TABLE 3
(Rich in Fe or Ni)

| Alloy | T_{g} | Tₓ | T_{L} |
|---|---|---|---|
| Fe65Mn13B17Y3 | 561 | 611 | 1082 |
| Fe67Mn13B17Y3 | 506 | 555 | 1082 |
| Fe67Mo13B17Y3 | 587 | 628 | 1157 |
| Fe70Mo13B17 | 549 | 577 | 1116 |
| Fe72Nb4B20Si4 | 569 | 607 | 1147 |
| (Fe72Nb4B20Si4)96Y4 | 632 | 660 | 1151 |
| Fe74Nb6B20 | 550 | 574 | 1156 |
| Fe74Nb6Y3B17 | 558 | 606 | 1118 |
| Fe77Nb6B17 | 524 | 541 | 1151 |
| Ni20Nb20P20 | 448 | 462 | |
| Ni55Zr12Al11Y22 | 423 | 460 | |
| Ni55Zr34Al11 | 562 | 580 | |
| Ni57.5Zr24Nb11Al7.5 | 576 | 609 | 1078 |
| Ni57.5Zr35Al7.5 | 550 | 575 | 1060 |
| Ni59Zr11Ti16Si2Sn3Nb9 | 569 | 609 | 999 |
| Ni59Zr20Ti16Si2Sn3 | 548 | 604 | 941 |
| Ni60Nb15Zr25 | 570 | 601 | 1132 |
| Ni60Nb30Ta10 | 661 | 688 | 1208 |
| Ni61Zr20Nb7Al4Ta8 | 603 | 661 | 1113 |
| Ni61Zr28Nb7Al4 | 575 | 625 | 1075 |

TABLE 4
(Rich in Mg, Mn, or Ca)

| Alloy | T_{g} | Tₓ | T_{L} |
|---|---|---|---|
| Mg65Ag25Gd10 | 202 | 202 | 443 |
| Mg65Cu15Ag10Gd10 | 143 | 186 | |
| Mg65Cu15Ag10Gd10 | 143 | 186 | 402 |
| Mg65Cu15Ag10Y10 | 155 | 196 | 413 |
| Mg65Cu15Ag5Pd5Gd10 | 157 | 199 | 414 |
| Mg65Cu20Ag5Y10 | 152 | 204 | 416 |
| Mg65Cu25Gd10 | 150 | 211 | 406 |
| Mg65Cu25Y10 | 153 | 215 | 457 |
| Mg65Cu7.5Ni7.5Ag5Zn5Gd10 | 167 | 204 | 453 |
| Mg65Cu7.5Ni7.5Ag5Zn5Y10 | 157 | 186 | 455 |
| Mg70Ni10Gd20 | 215 | 237 | |
| Mg75Ni15Gd10 | 190 | 231 | |
| Mg80Ni10Gd10 | 158 | 178 | |
| Mn55Al25Ni10Cu10 | 199 | 267 | 657 |
| Mn55Al25Ni10Cu5Co5 | 205 | 289 | 655 |
| Mn55Al25Ni20 | 220 | 277 | 682 |
| (Mn55Al25Ni10Cu5Co5)96C4 | 220 | 290 | 693 |
| Ca60Mg25Ni15 | 158 | 180 | 410 |
| Ca65Mg15Zn20 | 106 | 139 | 351 |

TABLE 5
(Rich in Ti or Zr)

| Alloy | T_{g} | Tₓ | T_{L} |
|---|---|---|---|
| Ti34Zr31Cu10Ni8Be17 | 352 | 378 | |
| Ti40Zr25Ni8Cu9Be18 | 348 | 395 | 675 |
| Ti40Zr28Cu9Ni7Be16 | 337 | 357 | |
| Ti45Ni15Cu25Sn3Be7Zr5 | 407 | 468 | 791 |
| Ti49Nb6Zr18Be14Cu7Ni6 | 348 | 375 | |
| Ti50Ni15Cu25Sn3Be7 | 415 | 460 | 849 |
| Ti50Ni15Cu32Sn3 | 413 | 486 | 932 |
| Ti50Zr15Be18Cu9Ni8 | 349 | 389 | 736 |
| Ti51Y4Zr18Be14Cu7Ni6 | 312 | 339 | |
| Ti55Zr18Be14Cu7Ni6 | 312 | 349 | |
| Ti65Be18Cu9Ni8 | 362 | 397 | 863 |
| Zr36Ti24Be40 | 354 | 440 | |
| Zr65Al7.5Cu12.6Ni10Ag5 | 386 | 436 | |
| Zr65Al7.5Cu17.5Ni10 | 380 | 443 | |

A glass transition temperature (“T_{g}”) of the alloy rich in Al is about 215° C. to about 290° C. as shown in Table 1, a glass transition temperature of the alloy rich in Cu is about 240° C. to about 520° C. as shown in Table 2, a glass transition temperature of the alloy rich in Fe or Ni is about 420° C. to about 625° C. as shown in Table 3, a glass transition temperature of the alloy rich in Mg, Mn, or Ca is about 100° C. to about 220° C. as shown in Table 4, and a glass transition temperature of the alloy rich in Ti or Zr is about 310° C. to about 42° C. as shown in Table 5.

The alloy of the amorphous metal may be represented by Formula 1:

AaBbCcDdEe, Formula 1

wherein in Formula 1, A, B, C, D, E, and F are each a different element, A is Al; B is yttrium (Y) or Ni; C is Fe, cerium (Ce), samarium (Sm), Y, gadolinium (Gd), dysprosium (Dy), erbium (Er), or lanthanum (La); D is vanadium (V), Ti, or Co; E is oxygen (O); and 80≦a≦90, 2≦b≦12, 3≦c≦10, 0≦d≦3, 0≦e≦2, and a+b+c+d+e=100.

The alloy of the amorphous metal may be represented by Formula 2:

AaBbCcDdEeFf, Formula 2

wherein in Formula 2, A, B, C, D, E, and F are each a different element. A is Cu; B is Zr, Ti, Y, Gd, or hafnium (Hf); C is Al, Zr, Ti, silver (Ag), beryllium (Be), niobium (Nb), or Ni; D is Ni, Ti, Ag, Al, indium (In), Nb, tantalum (Ta), or Y; E is Si, Ni, tin (Sn), Ag, or Co; F is Si; and 20≦a≦80, 15≦b≦35, 2≦c≦20, 0≦d≦15, 0≦e≦5, 0≦f≦3, and a+b+c+d+e+f=100.

The alloy of the amorphous metal may be represented by Formula 3:

AaBbCcDdEeFf, Formula 3

wherein in Formula 3, A, B, C, D, E, and F are each a different element; A is Fe or Ni; B is boron (B), Zr, Nb, Ti, or Y; C is molybdenum (Mo), Mn, Nb, Al, tantalum (Ta), Zr, Ti, or phosphorous (P); D is Y, Nb, Al, Si, or Sn; E is Al, Y, Si, or Sn; F is Si; and 20≦a≦80, 15≦b≦35, 2≦c≦20, 0≦d≦15, 0≦e≦5, 0≦f≦3, and a+b+c+d+e+f=100.

The alloy of the amorphous metal may be represented by Formula 4:

AaBbCcDdEeFf, Formula 4

wherein in Formula 4, A, B, C, O, E, and F are a different element; A is Mg, Mn, or Ca; B is Cu, Al, Ni, Gd, Ag, Y, Zn (Zn), or Mg; C is Ni, Gd, Ag, Y, Cu, or Mg; 0 is Cu, Ni, Ag, Gd, Y, palladium (Pd), Co, Zn, or carbon (C); E is Ag, Co, or Pd; F is Zn or C, and 55≦a≦80, 10≦b≦25, 5≦c≦20, 0≦d≦10, 0≦e≦5, 0≦f≦5, and a+b+c+d+e+f=100.

The alloy of the amorphous metal may be represented by Formula 5:

AaBbCcDdEeFf, Formula 5

wherein in Formula 5, A, B, C, O, E, and F are each a different element; A is Ti or Zr; B is Cu, Zr, or Be; C is Ni, Be, Zr, or Cu; D is Cu, Al, Ni, Sn, Ag, Y, or Nb; E is Ni, Ag, Sn, or Be; F is Y, Nb, or Zr; and 30≦a≦65, 10≦b≦40, 5≦c≦25, 0≦d≦10, 0≦e≦10, 0≦f≦7, and a+b+c+d+e+f=100.

An amount of the powder of the amorphous metal that sets the electrical conductivity of a final nanocomposite thermoelectric material to about 500 Siemens per centimeter (S/cm) to about 1500 S/cm, specifically about 600 (S/cm) to about 1400 S/cm, more specifically about 700 (S/cm) to about 1300 S/cm, may be used. When the electrical conductivity is below about 500 S/cm or exceeds about 1500 S/cm, a carrier concentration that maximizes thermoelectric performance may exceed the range of about 10¹⁹ to about 10²⁰ cm⁻³.

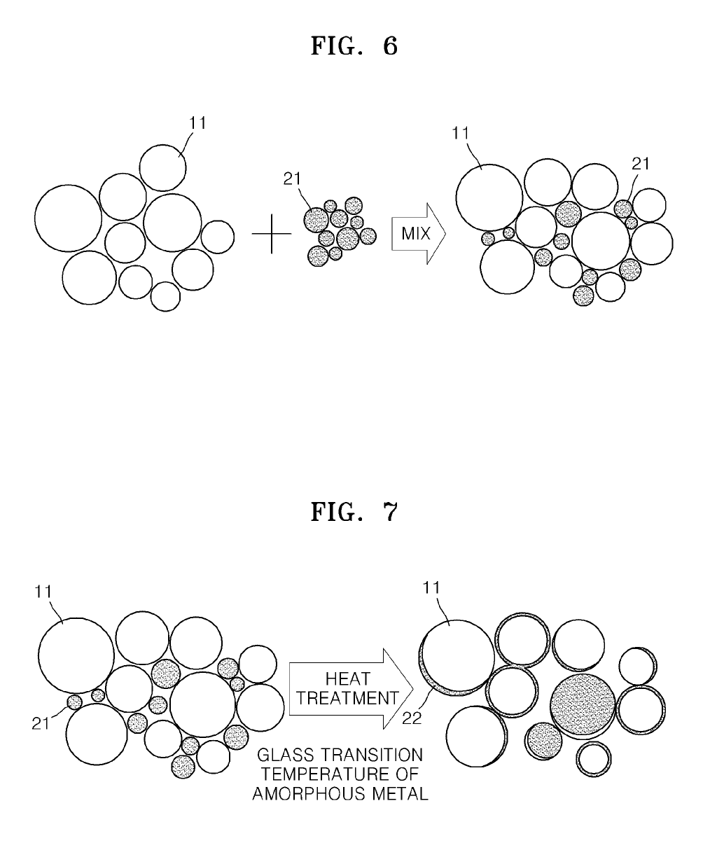

Then, a combined powder is prepared by combining the powder of the thermoelectric material and the powder of the amorphous metal in operation S120. FIG. 6 is a diagram schematically illustrating a process of forming the combined powder by combining the powder of a thermoelectric material 11 and the powder of an amorphous metal 21. The combined powder may be prepared by using any method of combining powders in a dry process. For example, the combined powder may be prepared by ball milling, attrition milling, or planetary milling.

Referring back to FIG. 5, the combined powder is heat-treated at a glass transition temperature of the amorphous metal in operation S130. FIG. 7 is a diagram schematically illustrating a process of wetting a surface of the powder of the thermoelectric material 11 with the amorphous metal 21 by heat treating the combined powder. Referring to FIG. 7, by heat-treating the amorphous metal 21 at a glass transition temperature, the amorphous metal 21 turns into a supercooled liquid state having high fluidity, and thus wets the surface of the powder of the thermoelectric material 11 in a thickness of about 1 nm to about 50 nm, specifically about 2 nm to about 40 nm, more specifically about 4 nm to about 30 nm, thereby forming a nanolayer 22 of the amorphous metal 21.

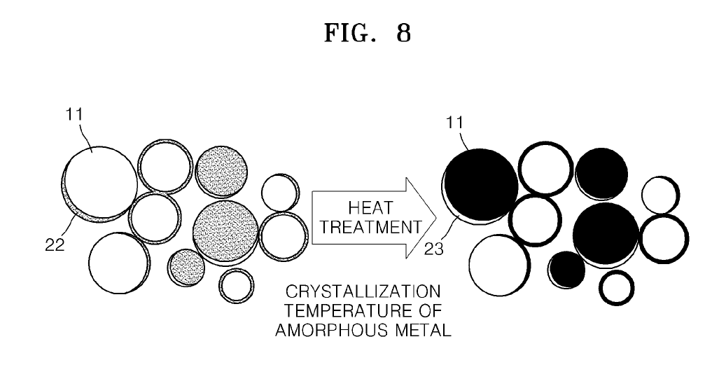

Referring back to FIG. 5, the powder of the thermoelectric material on which a nanolayer of the amorphous metal is formed is heat-treated at or above the crystallization temperature of the amorphous metal, in operation 5140. FIG. 8 is a diagram schematically illustrating a process of changing the nanolayer 22 of the amorphous metal of the surface of the powder of the thermoelectric material 11 to a nanolayer 23 of a crystalline metal. Referring to FIG. 8, the amorphous metal is crystallized via the heat treatment at or above the crystallization temperature, thereby forming the nanolayer 23 of the crystalline metal having a thickness from about 1 nm to about 50 nm, specifically about 2 nm to about 40 nm, more specifically about 4 nm to about 30 nm on the surface of the powder of the thermoelectric material 11. Alternatively, the heat treatment at the crystallization temperature of the amorphous metal may be continuously performed after the heat treatment at the glass transition temperature of the amorphous metal by increasing the glass transition temperature of the amorphous metal.

In addition, because the melting point of the thermoelectric material is higher than the glass transition temperature and the crystallization temperature of the amorphous metal, the thermoelectric material is not substantially affected during operations S130 and S140.

Referring back to FIG. 5, the powder of the thermoelectric material including a crystallized metal nanolayer is sintered to prepare a nanocomposite thermoelectric material of a thermoelectric material-metal nanolayer, in operation S150. Referring back to FIG. 3, the metal nanolayer 25 having the thickness from about 1 nm to 50 nm, specifically about 2 nm to about 40 nm, more specifically about 4 nm to about 30 nm is formed on the boundary of the plurality of grains 13 having the size (e.g., average largest particle size) of about 1 nm to about 100 micrometers (μm), specifically about 10 nm to about 10 μm, more specifically about 100 nm to about 1 μm.

### Example 1

Bi_{0.5}Sb_{1.5}Te₃ powder was used as a powder of a thermoelectric material. The Bi_{0.5}Sb_{1.5}Te₃ powder was prepared via mechanical alloying, wherein Bi, Sb, and Te, as a raw material powder, and a steel ball are put into and rotated in a jar formed of a hard metal, and the raw material powder is alloyed by mechanically shocking the raw material powder by using the steel ball. The Bi_{0.5}Sb_{1.5}Te₃ powder was separated to provide a powder of a size equal to or less than tens of micrometers by using a mechanical sieve (325 Mesh).

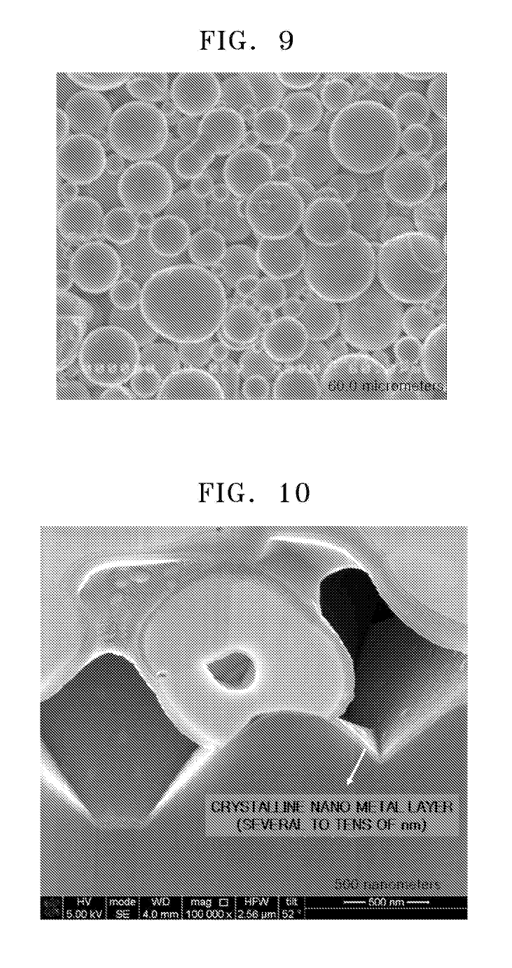

Cu₄₃Zr₄₃Al₇Ag₇ powder was used as a powder of an amorphous metal. The Cu₄₃Zr₄₃Al₇Ag₇ powder was obtained via gas atomization, and spherical particles having a particle size equal to or less than 45 μm were used. FIG. 9 is a scanning electron micrograph (“SEM”) of the powder of the amorphous metal synthesized via the gas atomization. Referring to FIG. 9, the powder of the amorphous metal has a size from several to tens of micrometers.

A mixed powder was prepared by adding 1 gram (g) (0.1 weight percent, wt %) of the Cu₄₃Zr₄₃Al₇Ag₇ powder to 10 g of Bi_{0.5}Sb_{1.5}Te₃ powder, and mixing thereof for 10 minutes using a high energy ball mill. Nitrogen was injected into the high energy ball mill so as to prevent a thermoelectric material from being oxidized by heat generated during ball milling.

The mixed powder was put into an alumina crucible, and a temperature of the mixed powder was increased to 450° C., which is a glass transition temperature of Cu₄₃Zr₄₃Al₇Ag₇, in a nitrogen atmosphere. The Cu₄₃Zr₄₃Al₇Ag₇ constituting the amorphous metal was turned into a supercooled liquid state having high fluidity at the glass transition temperature, and wetted the surface of the Bi_{0.5}Sb_{1.5}Te₃ powder constituting the thermoelectric material, thereby forming a layer having a thickness of about 1 nm to 50 nm. The Bi_{0.5}Sb_{1.5}Te₃ powder wet with the Cu₄₃Zr₄₃Al₇Ag₇ was again heat-treated at or above a temperature for crystallizing the Cu₄₃Zr₄₃Al₇Ag₇, i.e., the glass transition temperature, thereby preparing a powder, wherein a crystallized Cu₄₃Zr₄₃Al₇Ag₇ nanolayer is coated on a surface of the Bi_{0.5}Sb_{1.5}Te₃ powder.

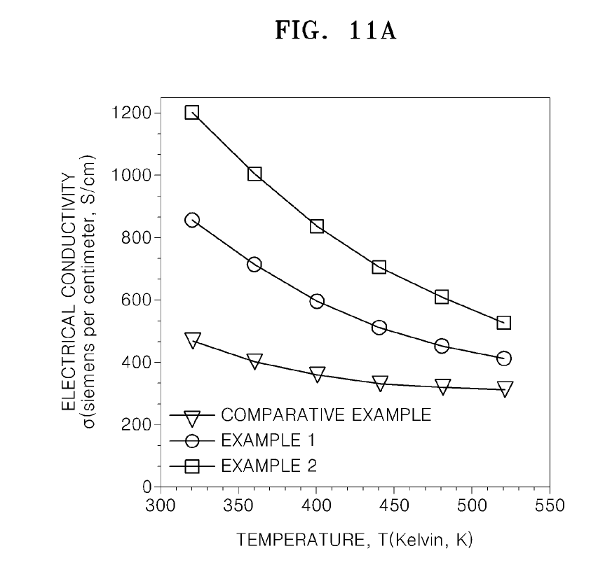

FIG. 10 is a cross-sectional SEM of a powder, wherein the crystallized Cu₄₃Zr₄₃Al₇Ag₇ nanolayer is coated on the surface of the Bi_{0.5}Sb_{1.5}Te₃ powder. Referring to FIG. 10, it is determined that the crystallized Cu₄₃Zr₄₃Al₇Ag₇ nanolayer having a thickness of tens of nm is coated on the surface of the Bi_{0.5}Sb_{1.5}Te₃ powder having a diameter of about 1 μm. Crystallization may be determined via X-ray diffraction analysis.

Then, a powder of a thermoelectric material including a crystallized metal nanolayer (Bi_{0.5}Sb_{1.5}Te₃+Cu₄₃Zr₄₃Al₇Ag₇) was sintered for 5 minutes under vacuum, at 70 megaPascals (MPa), and at 500° C. using spark plasma sintering, thereby preparing a bulk nanocomposite thermoelectric material.

### Example 2

A bulk nanocomposite thermoelectric material was prepared in the same manner as Example 1, except that 1.5 g (0.15 wt %) of the Cu₄₃Zr₄₃Al₇Ag₇ powder was added to 10 g of Bi_{0.5}Sb_{1.5}Te₃ powder.

### Example 3

Bi_{0.5}Sb_{1.5}Te₃ powder was used as powder of a thermoelectric material. The Bi_{0.5}Sb_{1.5}Te₃ powder was prepared via mechanical alloying, wherein Bi, Sb, and Te, which are a raw material powder, and a steel ball are put into and rotated in a jar formed of a hard metal, and the raw material powder is alloyed by mechanically shocking the raw material powder by using the steel ball. The Bi_{0.5}Sb_{1.5}Te₃ powder was separated to have a size equal to or less than tens of micrometers by using a mechanical sieve (325 Mesh).

Al_{85.35}Y₈Fe₆V_{0.65} powder was used as powder of an amorphous metal. The Al_{85.35}Y₈Fe₆V_{0.65} powder was obtained via gas atomization, and spherical particles having a particle size equal to or less than 45 μm were used.

A mixed powder was prepared by adding 1 g (0.1 wt %) of the Al_{85.35}Y₈Fe₆V_{0.65} powder to 10 g of Bi_{0.5}Sb_{1.5}Te₃ powder, and mixing thereof for 10 minutes by using a high energy ball mill. Nitrogen was injected into the high energy ball mill so as to prevent a thermoelectric material from being oxidized by heat generated during ball milling.

The mixed powder was put into an alumina crucible, and a temperature of the mixed powder was increased to 285° C., which is a glass transition temperature of Al_{85.35}Y₈Fe₆V_{0.65}, in a nitrogen atmosphere. The Al_{85.35}Y₈Fe₆V_{0.65} constituting the amorphous metal was turned into a supercooled liquid state having high fluidity at the glass transition temperature, and wetted the surface of the Bi_{0.5}Sb_{1.5}Te₃ powder constituting the thermoelectric material, thereby forming a layer having a thickness from about 1 nm to 50 nm. The Bi_{0.5}Sb_{1.5}Te₃ powder wet with the Al_{85.35}Y₈Fe₆V_{0.65} was again heat-treated at or above a temperature for crystallizing the Al_{85.35}Y₈Fe₆V_{0.65}, i.e., the glass transition temperature, thereby preparing a powder, wherein a crystallized Al_{85.35}Y₈Fe₆V_{0.65} nanolayer is coated on a surface of the Bi_{0.5}Sb_{1.5}Te₃ powder.

Then, a powder of a thermoelectric material including a crystallized metal nanolayer (Bi_{0.5}Sb_{1.5}Te₃+Al_{85.35}Y₈Fe₆V_{0.65}) was sintered for 5 minutes under vacuum, at 70 MPa, and at 500° C. by using spark plasma sintering, thereby preparing a bulk nanocomposite thermoelectric material.

### Example 4

A bulk nanocomposite thermoelectric material was prepared in the same manner as Example 3, except that 5 g (0.5 wt %) of the Al_{85.35}Y₈Fe₆V_{0.65} powder was added to 10 g of Bi_{0.5}Sb_{1.5}Te₃ powder.

### Comparative Example

Bi_{0.5}Sb_{1.5}Te₃ powder was prepared via mechanical alloying, wherein Bi, Sb, and Te, which are raw material powder, and a steel ball are put into and rotated in a jar formed of a hard metal, and the raw material powder was alloyed by mechanically shocking the raw material powder by using the steel ball. The Bi_{0.5}Sb_{1.5}Te₃ powder was separated into grains having a size equal to or less than tens of micrometers by using a mechanical sieve (325 Mesh).

Then, a bulk thermoelectric material is prepared by sintering the Bi_{0.5}Sb_{1.5}Te₃ powder for 5 minutes under vacuum, at 70 MPa, and at 500° C. using spark plasma sintering.

### Evaluation

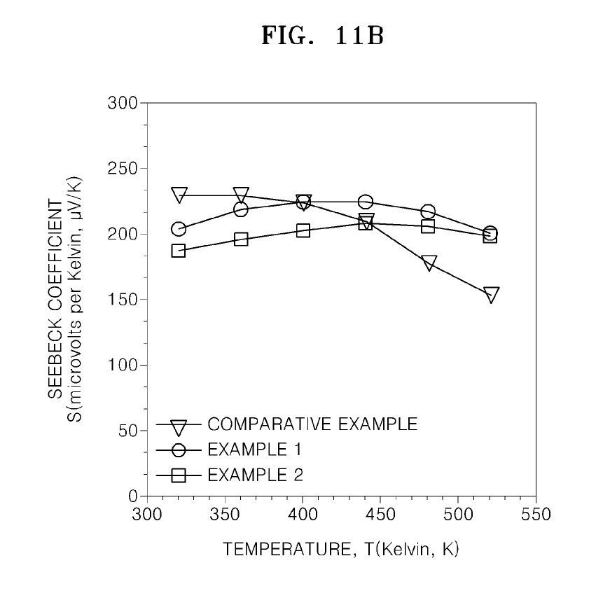

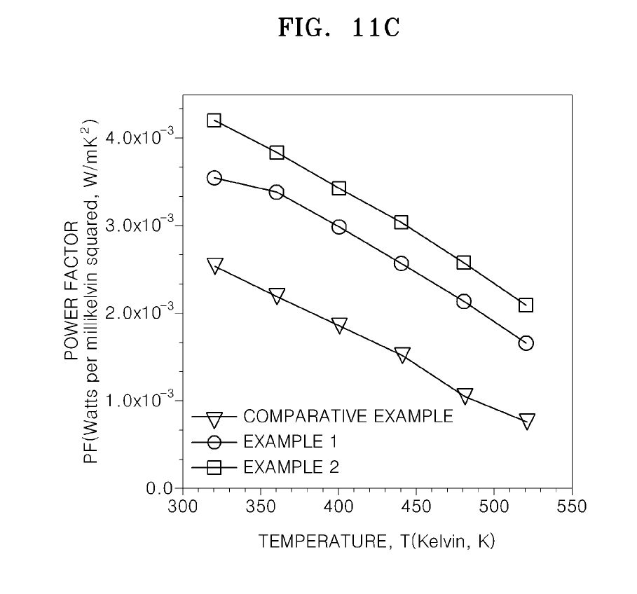

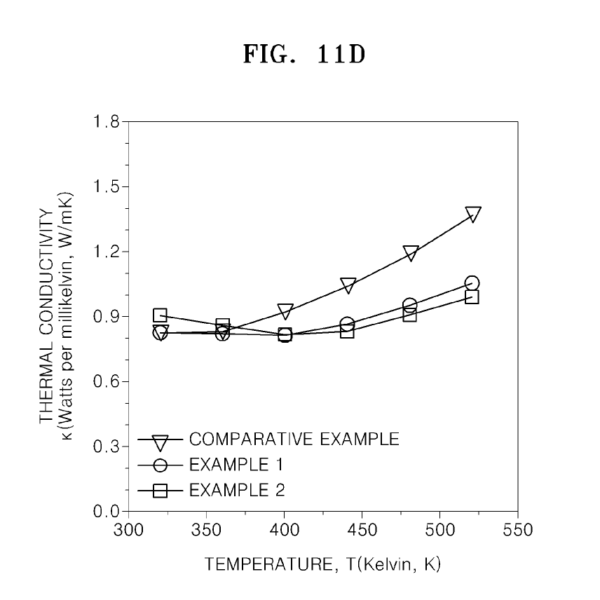

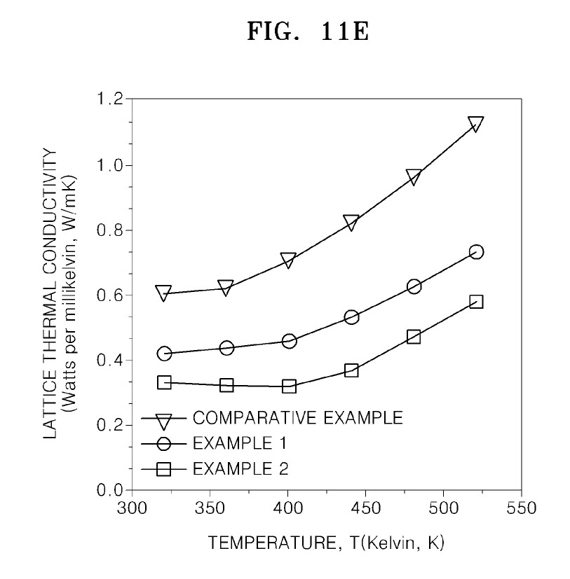

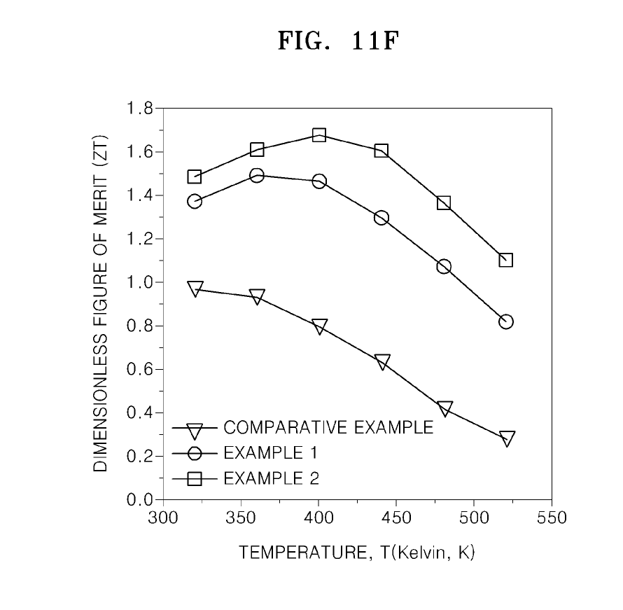

FIGS. 11A through 11F are graphs of thermoelectric characteristics of the thermoelectric materials of Examples 1 and 2 and the Comparative Example. FIG. 11A is a graph of electrical conductivity according to temperature, FIG. 11B is a graph of a Seebeck coefficient according to temperature, FIG. 11C is a graph of a power factor according to temperature, FIG. 11D is a graph of heat conductivity according to temperature, FIG. 11E is a graph of lattice heat conductivity according to temperature, and FIG. 11F is a graph of dimensionless figure of merit (ZT) according to temperature. Referring to FIGS. 11A through 11F, the electrical conductivity, the power factor, and the ZT of Examples 1 and 2 are higher than the Comparative Example, and the heat conductivity and lattice heat conductivity of Examples 1 and 2 are lower than the Comparative Example. In addition, the electrical conductivity, the power factor, and the ZT are higher in Example 2, wherein 0.15 wt % of the Cu₄₃Zr₄₃Al₇Ag₇ powder was used, than Example 1, wherein 0.1 wt % of Cu₄₃Zr₄₃Al₇Ag₇ powder was used.

While not wanting to be bound by theory, it is believed that these results are observed because a state of electrons is changed by introducing a metal nanolayer having suitable electrical conductivity. The ZT is increased as the Seebeck coefficient is increased according to a lattice heat conductivity reduction effect due to a nanolayer formed by the Cu₄₃Zr₄₃Al₇Ag₇ powder, and a carrier filtering effect due to existence of a highly conductive metal layer having a nanosize thickness (electrical conductivity of up to 5,000 S/cm that is about 10 times higher than that of the thermoelectric material).

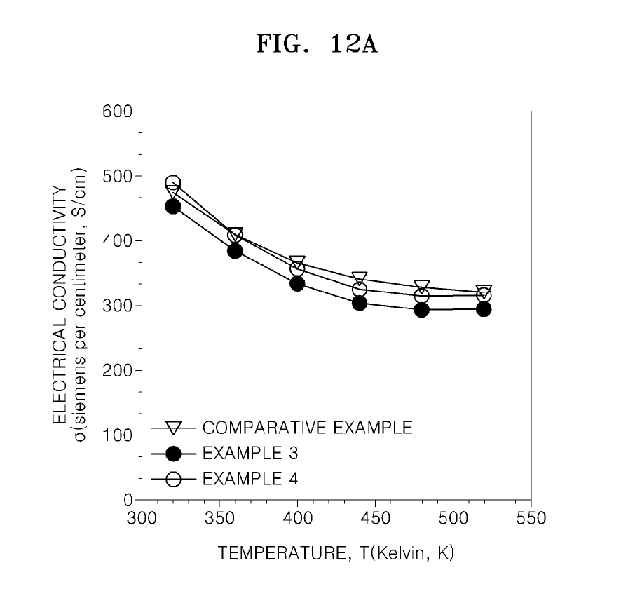

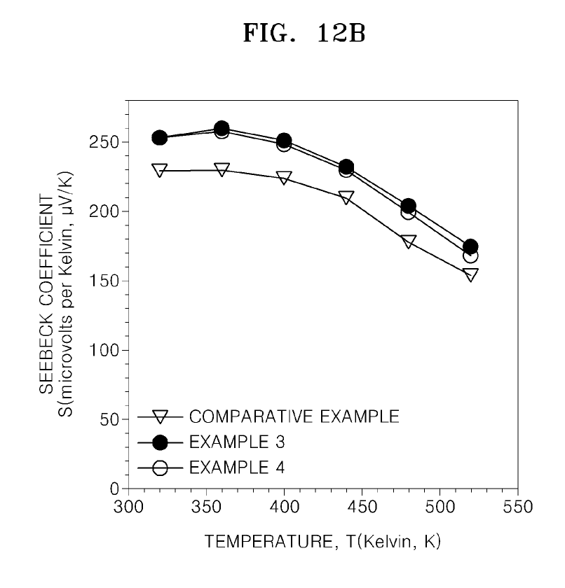

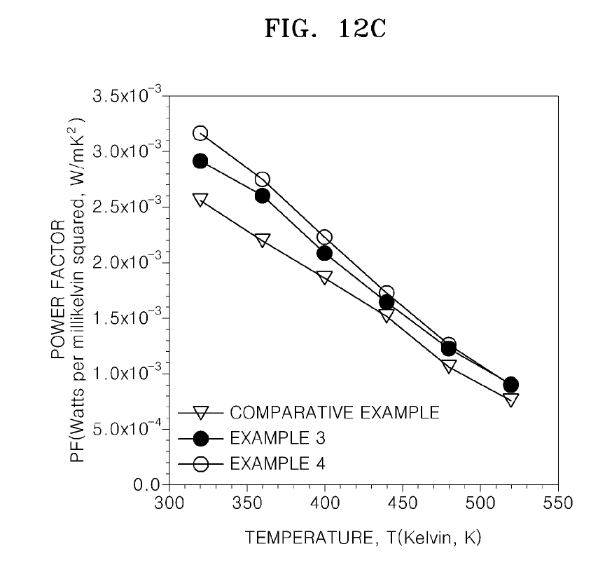

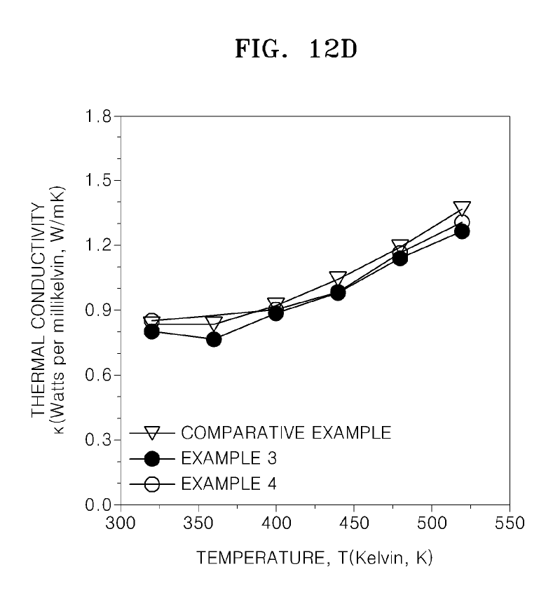

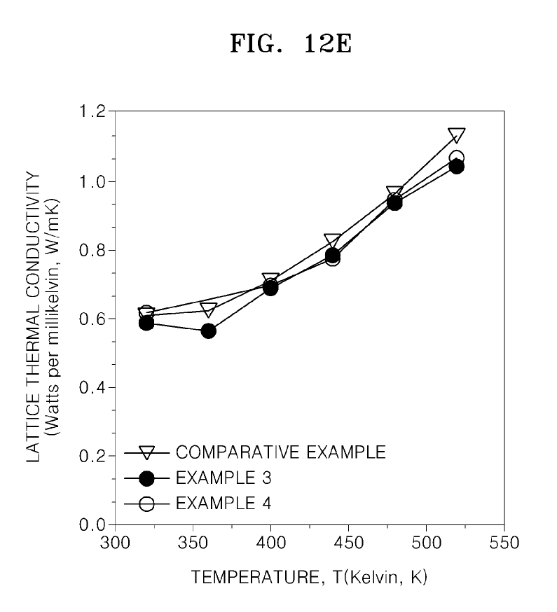

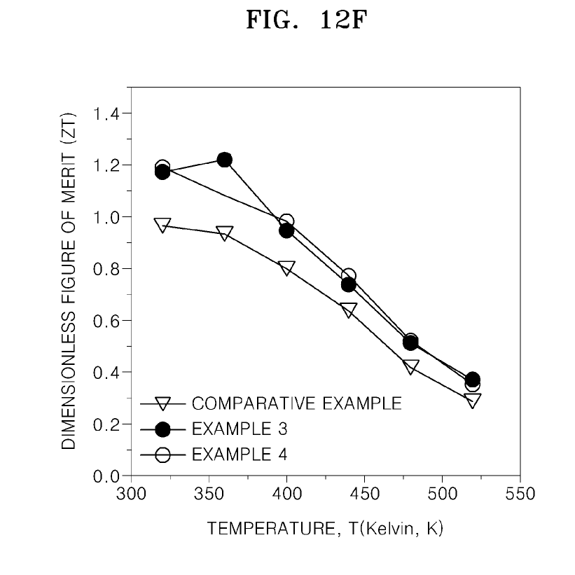

FIGS. 12A through 12F are graphs of thermoelectric characteristics of the thermoelectric materials of Examples 3 and 4 and the Comparative Example. FIG. 12A is a graph of electrical conductivity according to temperature, FIG. 12B is a graph of a Seebeck coefficient according to temperature, FIG. 12D is a graph of a power factor according to temperature, FIG. 12D is a graph of heat conductivity according to temperature, FIG. 12E is a graph of lattice heat conductivity according to temperature, and FIG. 12F is a graph of ZT according to temperature. Referring to FIGS. 12A through 12F, the electrical conductivity, the power factor, and the ZT of Examples 3 and 4 are higher than that of the Comparative Example, and heat conductivity and lattice heat conductivity of Examples 3 and 4 are lower than that of the Comparative Example.

While not wanting to be bound by theory, it is believed that these results are observed because a state of electrons is changed by introducing a metal nanolayer having suitable electrical conductivity as in Examples 1 and 2. The ZT is increased as the Seebeck coefficient is increased according to a lattice heat conductivity reduction effect due to a nanolayer formed by the Al_{85.35}Y₈Fe₆V_{0.65} powder, and a carrier filtering effect due to existence of a highly conductive metal layer having a nanosize thickness (electrical conductivity up to 5,000 S/cm that is about 10 times higher than that of the thermoelectric material).

As described above, according to an embodiment, by introducing a metal nanolayer to a boundary of grains of a thermoelectric material, a quantum confinement effect and a PGEC concept are provided in a bulk material, thereby forming a powder of the thermoelectric material and a bulk thermoelectric material, which have improved thermoelectric performance.

It shall be understood that the exemplary embodiments described herein should be considered in a descriptive sense only and not for purposes of limitation. Descriptions of features, advantages, or aspects within each embodiment should be considered as available for other similar features, advantages, or aspects in other embodiments.

What is claimed is:

1. A bulk nanocomposite thermoelectric material comprising:
a plurality of grains of a thermoelectric material; and
a metal nanolayer on a boundary of the plurality of grains, wherein
a glass transition temperature and a crystallization temperature of the nano metal are lower than a melting point of the thermoelectric material.

2. The bulk nanocomposite thermoelectric material of claim 1, wherein each grain of the plurality of grains has a diameter of about 1 nanometer to about 100 micrometers.

3. The bulk nanocomposite thermoelectric material of claim 1, wherein the metal nanolayer has a thickness of about 1 nanometer to about 50 nanometers.

4. The bulk nanocomposite thermoelectric material of claim 1, wherein the nanolayer is crystalline.

5. The bulk nanocomposite thermoelectric material of claim 1, wherein the thermoelectric material comprises
a Bi—Te material comprising at least two of Bi, Sb, Te, and Se;
a Pb—Te material comprising Pb and Te;
a Co—Sb material comprising Sb and at least one of Co and Fe;
a Si—Ge material comprising Si and Ge; or
a Fe—Si material comprising Fe and Si.

6. The bulk nanocomposite thermoelectric material of claim 1, wherein the metal nanolayer comprises an alloy of Formula 1:
AaBbCcDdEe, Formula 1
wherein in Formula 1,
A, B, C, D, and E are each a different element;
A is Al;
B is Y or Ni;
C is Fe, Ce, Sm, Y, Gd, Dy, Er, or La;
D is V, Ti, or Co;
E is O; and
80≦a≦90, 2≦b≦12, 3≦c≦10, 0≦d≦3, 0≦e≦2, and a+b+c+d+e=100.

7. The bulk nanocomposite thermoelectric material of claim 6, wherein a glass transition temperature of the alloy is about 215° C. to about 290° C.

8. The bulk nanocomposite thermoelectric material of claim 1, wherein the metal nanolayer comprises an alloy of Formula 2:
AaBbCcDdEeFf, Formula 2
wherein in Formula 2,
A, B, C, D, E, and F are each a different element;
A is Cu;
B is Zr, Ti, Y, Gd, or Hf;
C is Al, Zr, Ti, Ag, Be, Nb, or Ni;
D is Ni, Ti, Ag, Al, In, Nb, Ta, or Y;
E is Si, Ni, Sn, Ag, or Co;
F is Si; and
30≦a≦60, 30≦b≦50, 0≦c≦30, 0≦d≦20, 0≦e≦10, 0≦f≦2, and a+b+c+d+e+f=100.

9. The bulk nanocomposite thermoelectric material of claim 8, wherein a glass transition temperature of the alloy is about 240° C. to about 52° C.

10. The bulk nanocomposite thermoelectric material of claim 1, wherein the metal nanolayer comprises an alloy of Formula 3:
AaBbCcDdEeFf, Formula 3
wherein in Formula 3,
A, B, C, D, E, and F are each a different element;
A is Fe or Ni;
B is B, Zr, Nb, Ti, or Y;
C is Mo, Mn, Nb, Al, Ta, Zr, Ti, or P;
D is Y, Nb, Al, Si, or Sn, E is Al, Y, Si, or Sn;
F is Si; and
20≦a≦80, 15≦b≦35, 2≦c≦20, 0≦d15, 0≦e5, 0≦f≦3, and a+b+c+d+e+f=100.

11. The bulk nanocomposite thermoelectric material of claim 10, wherein a glass transition temperature of the alloy is about 420° C. to about 625° C.

12. The bulk nanocomposite thermoelectric material of claim 1, wherein the metal nanolayer comprises an alloy of Formula 4:
AaBbCcDdEeFf, Formula 4
wherein in Formula 4,
A, B, C, D, E, and F are a different element;
A is Mg, Mn, or Ca;
B is Cu, Al, Ni, Gd, Ag, Y, Zn, or Mg;
C is Ni, Gd, Ag, Y, Cu, or Mg;
D is Cu, Ni, Ag, Gd, Y, Pd, Co, Zn, or C;
E is Ag, Co, or Pd, and F is Zn or C; and
55≦a≦80, 10≦b≦25, 5≦c≦20, 0≦d≦10, 0≦e≦5, 0≦f≦5, and a+b+c+d+e+f=100.

13. The bulk nanocomposite thermoelectric material of claim 12, wherein a glass transition temperature of the alloy is about 100° C. to about 220° C.

14. The bulk nanocomposite thermoelectric material of claim 1, wherein the metal nanolayer comprises an alloy of Formula 5
AaBbCcDdEeFf, Formula 5
wherein in Formula 5,
A, B, C, D, E, and F are each a different element,
A is Ti or Zr;
B is Cu, Zr, or Be;
C is Ni, Be, Zr, or Cu;
D is Cu, Al, Ni, Sn, Ag, Y, or Nb;
E is Ni, Ag, Sn, or Be;
F is Y, Nb, or Zr; and
30≦a≦65, 10≦b≦40, 5≦c≦25, 0≦d≦10, 0≦e≦10, 0≦f≦7, and a+b+c+d+e+f=100.

15. The bulk nanocomposite thermoelectric material of claim 14, wherein a glass transition temperature of the alloy is about 310° C. to about 420° C.

16. The bulk nanocomposite thermoelectric material of claim 1, wherein
the metal nanolayer comprises at least a first layer and a second layer,
each of the at least first layer and the second layer comprises a crystalline and
at least one of a glass transition temperature and a crystallization temperature of the first layer is different than a glass transition temperature and a crystallization temperature of the second layer, respectively.

17. The bulk nanocomposite thermoelectric material of claim 1, wherein the metal nanolayer comprises an alloy crystallized from at least a first amorphous metal and a second amorphous metal, wherein at least one of a glass transition temperature and a crystallization temperature of the first amorphous metal is different than a glass transition temperature and a crystallization temperature of the second amorphous metal, respectively.

18. The bulk nanocomposite thermoelectric material of claim 1, wherein the nano metal is crystallized from an amorphous metal.

19. A nanocomposite thermoelectric material comprising:
a bulk thermoelectric material; and
a metal nanolayer on a surface of the bulk thermoelectric material,
wherein the metal nanolayer comprises an amorphous metal.

20. The nanocomposite thermoelectric material of claim 19, wherein the bulk thermoelectric material has a particle diameter of about 1 nanometer to about 100 micrometers.

21. The nanocomposite thermoelectric material of claim 19, wherein the bulk thermoelectric material comprises
a Bi—Te material comprising at least two of Bi, Sb, Te, and Se,
a Pb—Te material comprising Pb and Te,
a Co—Sb material comprising Sb and at least one of Co and Fe,
a Si—Ge material comprising Si and Ge, or
a Fe—Si material comprising Fe and Si.

22. The nanocomposite thermoelectric material of claim 19, wherein the metal nanolayer comprises an alloy of Formula 6
AaBbCcDdEeFf, Formula 6
wherein A, B, C, D, E, and F are each a different element;
A is Al, Cu, Fe, Ni, Mg, Mn, Ca, Ti, or Zr;
B is Y, Ni, Zr, Ti, Gd, Hf, B, Nb, Cu, Al, Ag, Zn, Mg, or Be;
C is Fe, Ce, Sm, Y, Gd, Dy, Er, La, Al, Zr, Ti, Ag, Be, Nb, Ni, Mo, Mn, Ta, P, Y, Cu, or Mg;
D is V, Ti, Co, Ni, Ag, Al, In, Nb, Ta, Y, Nb, Si, Sn, Cu, Gd, Y, Pd, Zn, or C;
E is O, Si, Ni, Sn, Ag, Co, Al, Y, Pd, or Be;
F is Si, Zn, C, Y, Nb, or Zr; and
20≦a≦90, 2≦b≦50, 0≦c≦30, 0≦d≦12, 0≦e≦10, 0≦f≦7, and a+b+c+d+e+f=100.

23. The nanocomposite thermoelectric material of claim 19, wherein the nanocomposite thermoelectric material is in the form of powder.

24. A method of preparing a bulk nanocomposite thermoelectric material, the method comprising:
forming a powder of a thermoelectric material;
forming a powder of an amorphous metal having a glass transition temperature and a crystallization temperature that are lower than a melting point of the thermoelectric material;
combining the powder of the thermoelectric material and the powder of the amorphous metal to form a combination;
firstly heat treating the combination at about the glass transition temperature of the amorphous metal to wet a surface of the powder of the thermoelectric material with the amorphous metal;
secondly heat treating the firstly heat treated combination at or above the crystallization temperature of the amorphous metal to crystallize the amorphous metal; and
sintering the secondly heat treated combination at or above a melting point of the thermoelectric material to prepare the bulk nanocomposite thermoelectric material.

25. The method of claim 24, wherein the powder of the thermoelectric material has a particle diameter of about 1 nanometer to about 100 micrometers.

26. The method of claim 24, wherein the powder of the amorphous metal has a particle diameter of about 1 nanometer to about 10 micrometers.

27. The method of claim 24, wherein the thermoelectric material comprises:
a Bi—Te material comprising at least two of Bi, Sb, Te, and Se,
a Pb—Te material comprising Pb and Te,
a Co—Sb material comprising Sb and at least one of Co and Fe,
a Si—Ge material comprising Si and Ge, or
a Fe—Si material comprising Fe and Si.

28. The method of claim 24, wherein amorphous metal comprises an alloy of Formula 1
AaBbCcDdEe, Formula 1
wherein in Formula 1,
A, B, C, D, and E are each a different element;
A is Al;
B is Y or Ni;
C is Fe, Ce, Sm, Y, Gd, Dy, Er, or La;
D is V, Ti, or Co;
E is O; and
80≦a≦90, 2≦b≦12, 3≦c≦10, 0≦d≦3, 0≦e≦2, and a+b+c+d+e=100.

29. The method of claim 26, wherein a glass transition temperature of the alloy is about 215° C. to about 290° C.

30. The method of claim 24, wherein the amorphous metal comprises an alloy of Formula 2
AaBbCcDdEeFf, Formula 2
wherein in Formula 2,
A, B, C, D, E, and F are each a different element;
A is Cu;
B is Zr, Ti, Y, Gd, or Hf;
C is Al, Zr, Ti, Ag, Be, Nb, or Ni;
D is Ni, Ti, Ag, Al, In, Nb, Ta, or Y;
E is Si, Ni, Sn, Ag, or Co; and
F is Si; and
30≦a≦60, 30≦b≦50, 0≦c≦30, 0≦d≦20, 0≦e≦10, 0≦f≦2, and a+b+c+d+e+f=100.

31. The method of claim 30, wherein a glass transition temperature of the alloy is about 240° C. to about 520° C.

32. The method of claim 24, wherein the amorphous metal comprises an alloy of Formula 3:
AaBbCcDdEeFf, Formula 3
wherein in Formula 3,
A, B, C, D, E, and F are each a different element;
A is Fe or Ni;
B is B, Zr, Nb, Ti, or Y;
C is Mo, Mn, Nb, Al, Ta, Zr, Ti, or P;
D is Y, Nb, Al, Si, or Sn;
E is Al, Y, Si, or Sn;
F is Si; and
20≦a≦80, 15≦b≦35, 2≦c≦20, 0≦d≦15, 0≦e≦5, 0≦f≦3, and a+b+c+d+e+f=100.

33. The method of claim 32, wherein a glass transition temperature of the alloy is about 420° C. to about 625° C.

34. The method of claim 24, wherein the amorphous metal comprises an alloy of Formula 4:
AaBbCcDdEeFf, Formula 4
wherein in Formula 4,
A, B, C, D, E, and F are each a different element;
A is Mg, Mn, or Ca;
B is Cu, Al, Ni, Gd, Ag, Y, Zn, or Mg;
C is Ni, Gd, Ag, Y, Cu, or Mg;
D is Cu, Ni, Ag, Gd, Y, Pd, Co, Zn, or C;
E is Ag, Co, or Pd;
F is Zn or C; and
55≦a≦80, 10≦b≦25, 5≦c≦20, 0≦d≦10, 0≦e≦5, 0≦f≦5, and a+b+c+d+e+f=100.

35. The method of claim 34, wherein a glass transition temperature of the alloy is about 100° C. to about 220° C.

36. The method of claim 24, wherein the amorphous metal comprises an alloy of Formula 5:
AaBbCcDdEeFf, Formula 5
wherein in Formula 5,
A, B, C, D, E, and F are each a different element;
A is Ti or Zr;
B is Cu, Zr, or Be;
C is Ni, Be, Zr, or Cu;
D is Cu, Al, Ni, Sn, Ag, Y, or Nb;
E is Ni, Ag, Sn, or Be;
F is Y, Nb, or Zr; and
30≦a≦65, 10≦b≦40, 5≦c≦25, 0≦d≦10, 0≦e≦10, 0≦f≦7, and a+b+c+d+e+f=100.

37. The method of claim 34, wherein a glass transition temperature of the alloy is about 310° C. to about 420° C.
